(19) United States
(12) Patent Application Publication
(10) Pub. No.: US 2026/0073954 A1
(43) Pub. Date: Mar. 12, 2026

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventor: Yosuke KANNO, Yokkaichi Mie (JP)

(21) Appl. No.: 19/069,113

(22) Filed: Mar. 3, 2025

(30) Foreign Application Priority Data
Sep. 12, 2024 (JP) 2024-158073

(51) Int. Cl. G11C 5/06; H10B 43/10; H10B 43/27

(52) U.S. Cl. CPC G11C 5/063; H10B 43/10; H10B 43/27

(57) ABSTRACT

A semiconductor memory device includes a stacked body including a plurality of first layers and a plurality of second layers alternately stacked one by one, a plurality of slits extending in the stacked body in a stacking direction of the stacked body and in a first direction intersecting the stacking direction, the slits dividing the stacked body in a second direction intersecting the first direction and the stacking direction, and a plurality of pillars disposed between the plurality of slits and extending in the stacked body in the stacking direction.

### CROSS-REFERENCE TO RELATED APPLICATION

This application is based upon and claims the benefit of priority from Japanese Patent Application No. 2024-158073, filed Sep. 12, 2024, the entire contents of which are incorporated herein by reference.

### FIELD

Embodiments described herein relate generally to a semiconductor memory device and a method for manufacturing a semiconductor memory device.

### BACKGROUND

A semiconductor memory device such as a three-dimensional nonvolatile memory includes a stacked body in which a plurality of conductive layers are stacked, for example, and memory cells are arranged three-dimensionally at each height position of the conductive layers. To prevent characteristic fluctuation of the memory cells, vicinity of an end portion of the stacked body serves as a dummy region.

### BRIEF DESCRIPTION OF THE DRAWINGS

FIGS. 1A and 1B are diagrams schematically showing a structure of a semiconductor memory device according to an embodiment.

FIG. 2 is a schematic view showing a structure of the semiconductor memory device.

FIGS. 3A to 3D are cross-sectional views showing the structure of the semiconductor memory device.

FIGS. 4A to 4D are diagrams illustrating a part of a method for manufacturing the semiconductor memory device.

FIGS. 5A to 5D are diagrams illustrating a part of the method for manufacturing the semiconductor memory device.

FIGS. 6A to 6C are diagrams illustrating a part of the method for manufacturing the semiconductor memory device.

FIGS. 7A to 7D are diagrams illustrating a part of the method for manufacturing the semiconductor memory device.

FIGS. 8A to 8D are diagrams illustrating a part of the method for manufacturing the semiconductor memory device.

FIGS. 9A to 9C are diagrams illustrating a part the method for manufacturing the semiconductor memory device.

FIGS. 10A and 10B are cross-sectional views showing a structure of a semiconductor memory device according to a modification example.

### DETAILED DESCRIPTION

Embodiments provide a semiconductor memory device and a method for manufacturing a semiconductor memory device capable of reducing a dummy region in an end portion of a stacked body.

In general, according to one embodiment, a semiconductor memory device comprises a stacked body including a plurality of first layers and a plurality of second layers alternately stacked one by one, a plurality of slits extending in the stacked body in a stacking direction of the stacked body and in a first direction intersecting the stacking direction, the slits dividing the stacked body in a second direction intersecting the first direction and the stacking direction, and a plurality of pillars disposed between the plurality of slits and extending in the stacked body in the stacking direction. An upper end portion of a first slit disposed closest to an end portion of the stacked body in the second direction among the plurality of slits is fully covered with a first strip of first material extending in the first direction and having a width in the second direction that is substantially the same as that of the upper end portion of the first slit. An upper end portion of each of a plurality of second slits excluding the first slit among the plurality of slits is partially covered with second strips of the first material, the second strips each having a width in the second direction that is substantially the same as that of the upper end portion of the second slit that the second strips are partially covering.

Hereinafter, embodiments of this disclosure will be described with reference to the drawings. The embodiments described below are not intended to limit the present disclosure. The elements in the following embodiment include those that can be conceived by those skilled in the art or those that are substantially the same.

### Structure Example of Semiconductor Memory Device

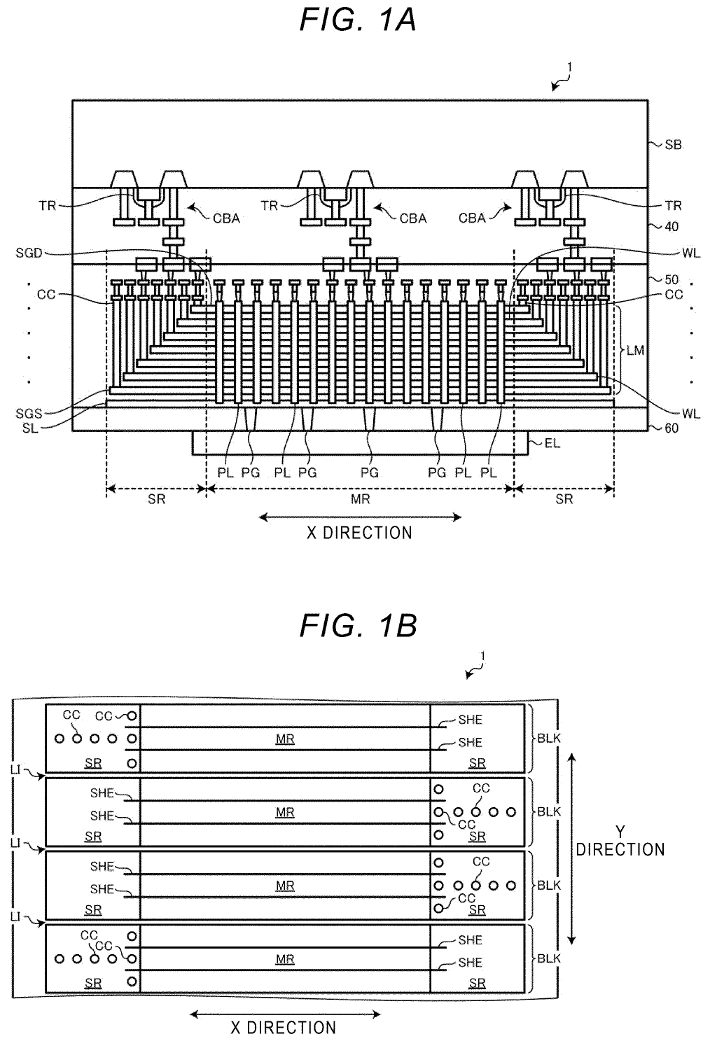

FIGS. 1A and 1B are diagrams schematically showing a structure of a semiconductor memory device 1 according to an embodiment. More specifically, FIG. 1A is a cross-sectional view of the semiconductor memory device 1 along an X direction, and FIG. 1B is a schematic plan view showing a layout of the semiconductor memory device 1.

Hatching is omitted in FIG. 1A considering visibility of the drawing. In FIG. 1A, structures that are not necessarily disposed on the same cross section are shown, and a portion of an upper layer wiring and the like is omitted.

In the specification, both an X direction and a Y direction are directions along a plane of a word line WL, and the X direction and the Y direction are perpendicular to each other. An electrical lead direction of the word line WL may be referred to as a first direction, and the first direction is a direction along the X direction. A direction intersecting the first direction may be referred to as a second direction, and the second direction is a direction along the Y direction. Since the semiconductor memory device 1 may include manufacturing errors, the first direction and the second direction are not necessarily perpendicular to each other.

As shown in FIG. 1A, the semiconductor memory device 1 includes, in order from a lower side of the figure, an electrode film EL, a source line SL, one or more select gate lines SGS, a plurality of word lines WL, one or more select gate lines SGD, and a semiconductor substrate SB provided with a peripheral circuit CBA.

The source line SL is disposed above the electrode film EL via an insulating layer 60. A plurality of plugs PG are disposed in the insulating layer 60, and electrical connection between the source line SL and the electrode film EL is maintained via the plugs PG. Though not shown, an electrode pad that supplies power and signals to the semiconductor memory device 1 from the outside is provided in the same layer as the electrode film EL. Above the source line SL, the select gate line SGS, the plurality of word lines WL, and the select gate line SGD are stacked in this order.

As shown in FIGS. 1A and 1B, a memory region MR is disposed in a central portion of the plurality of word lines WL and the like in the X direction, and stepped regions SR are disposed in both end portions of the plurality of word lines WL and the like in the X direction, respectively. The memory region MR and the stepped regions SR are divided into a plurality of regions by a plurality of plate-like portions LI penetrating the plurality of word lines WL and the like and extending in a direction along the X direction. As described later, the plate-like portions LI are formed from slits.

A region that is disposed between the plate-like portions LI adjacent to each other in the Y direction and includes the memory region MR and the stepped regions SR is referred to as a block region BLK. As described below, a plurality of memory cells storing data in a nonvolatile manner are included in the memory region MR, and the block region BLK is an erase unit of data.

A plurality of separation layers SHE penetrating the select gate line SGD and extending in a direction along the X direction are disposed between the plate-like portions LI adjacent to each other in the Y direction. The plurality of separation layers SHE extend in a direction along the X direction across the entire memory region MR, and reach portions of the stepped regions SR in both end portions in the X direction.

In the memory region MR, a plurality of pillars PL penetrating the word line WL and the select gate lines SGD and SGS in the stacking direction are disposed. The lower end of the pillar PL reaches the source line SL. A plurality of memory cells are formed at intersections between the pillars PL and the word lines WL. As a result, the semiconductor memory device 1 is formed as a three-dimensional nonvolatile memory in which memory cells are arranged three-dimensionally in the memory region MR, for example. Accordingly, the semiconductor memory device 1 is also a three-dimensional nonvolatile memory.

In the stepped region SR, a plurality of word lines WL and the select gate lines SGD and SGS are processed into a stepped shape and terminated. Here, since the plurality of word lines WL and the select gate lines SGD and SGS forming a terrace portion spread from an upper layer side to a lower layer side according to an increase in a distance from the memory region MR in the X direction, a height position of the terrace portion is lowered to the source line SL side.

In the specification, a direction in which terrace surfaces of the plurality of word lines WL and the select gate lines SGD and SGS face is defined as an upper side of the semiconductor memory device 1.

The above-described separation layer SHE extends from the memory region MR to a portion where the select gate line SGD of the stepped region SR is processed into a stepped shape. As a result, in one block region BLK, the select gate line SGD is separated into a plurality of regions. In other words, the separation layer SHE penetrates a portion on the upper layer side than the plurality of word lines WL so that the upper layer portion is partitioned into patterns of a plurality of select gate lines SGD.

In the terrace portion of the step formed by each of the plurality of word lines WL and the select gate lines SGD and SGS, contacts CC connected to the word lines WL and the select gate lines SGD and SGS in each layer are disposed. In the word lines WL and the select gate line SGS, one contact CC is connected for one layer. In the select gate line SGD, one contact CC is connected for each partition separated by the separation layer SHE for one layer.

Here, in one block region BLK, a plurality of contacts CC are disposed on one side of both sides of the stepped region SR in the X direction. As viewed from one side in the X direction, for example, the plurality of contacts CC are disposed for every two block regions BLK.

That is, in the example of FIG. 1B, in a block region BLK of an uppermost portion of the paper, the plurality of contacts CC are disposed in, for example, the stepped region SR on the left side of the paper of the stepped regions SR in both end portions in the X direction. In block regions BLK one layer below and two layers below the above-described uppermost block region BLK, the plurality of contacts CC are disposed in the stepped region SR on the right side of the paper of the stepped regions SR in both end portions in the X direction. In a block region BLK of a lowermost portion of the paper, the plurality of contacts CC are disposed in the stepped region SR on the left side again.

Accordingly, the contacts CC of each of the stepped regions SR in both end portions in the X direction shown in FIG. 1A belong to different block regions BLK and are actually not positioned on the same cross section.

The word lines WL and the like stacked in multiple layers are each led out by the contacts CC. More specifically, from the contacts CC, a write voltage, a read voltage, and the like are applied to the memory cell provided in the memory region MR in the center portion of the plurality of word lines WL via the word line WL at the same height position as the memory cell.

The plurality of word lines WL, the select gate lines SGD and SGS, the pillars PL, and the contacts CC are covered with an insulating layer 50. The insulating layer 50 also extends around the configuration including the plurality of word lines WL and the like.

The semiconductor substrate SB above the insulating layer 50 covering the above-described structure is, for example, a silicon substrate. The peripheral circuit CBA including a transistor TR, a wiring, and the like is disposed on a surface of the semiconductor substrate SB. Various voltages applied from the contacts CC to the memory cell are controlled by the peripheral circuit CBA electrically connected to the contacts CC. As a result, the peripheral circuit CBA controls electrical operations of the memory cell.

The peripheral circuit CBA is covered with an insulating layer 40, and the semiconductor memory device 1 including the plurality of word lines WL, the select gate lines SGD and SGS, the pillars PL, and the contacts CC, and the like and the peripheral circuits CBA is formed by bonding the insulating layer 40 to the insulating layer 50 covering the plurality of word lines WL and the like.

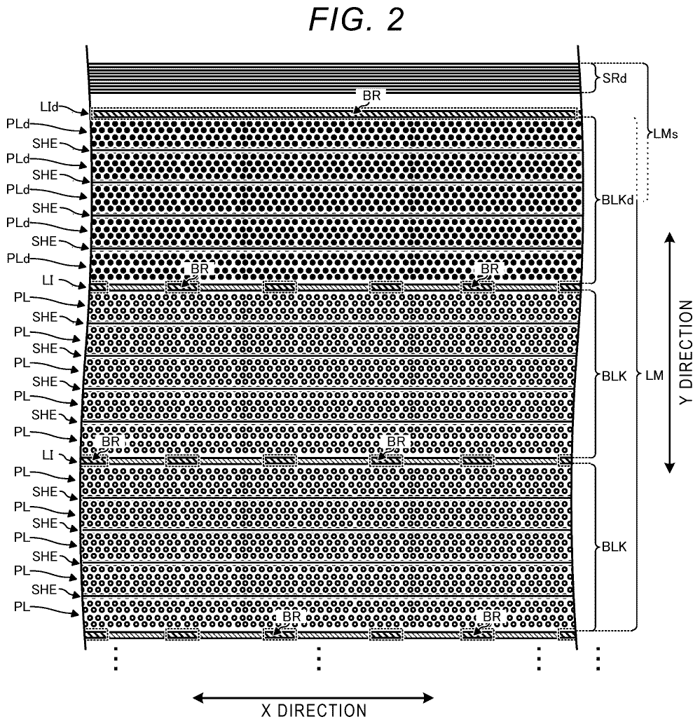

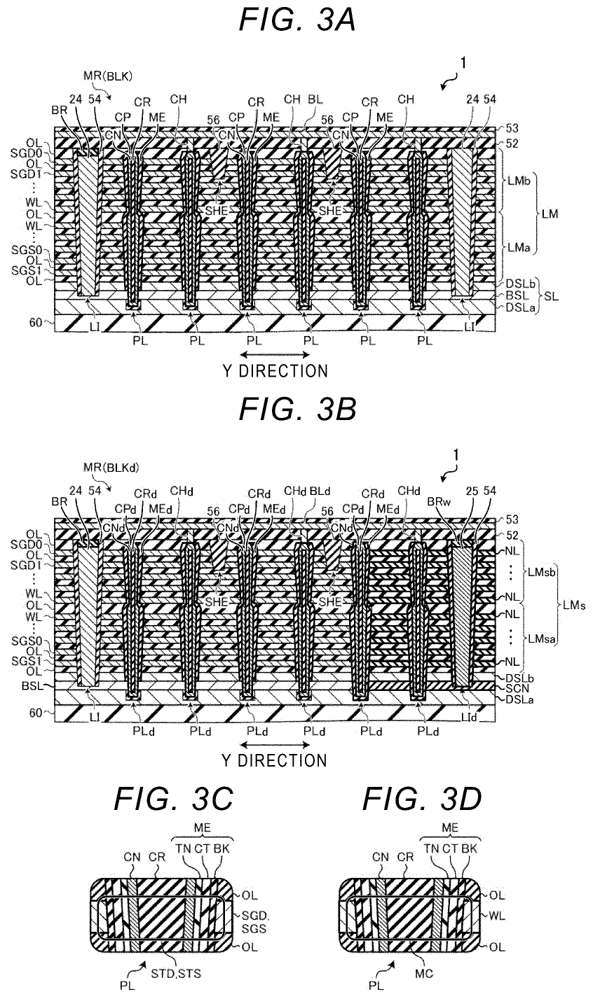

Next, a detailed structure of the semiconductor memory device 1 will be described with reference to FIGS. 2 to 3D.

FIG. 2 is a schematic view showing a structure of the semiconductor memory device 1. In more detail, FIG. 2 is an XY cross-sectional view of the semiconductor memory device 1 at a height position of the select gate line SGD, and shows the vicinity of an end portion position in the Y direction of a stacked body LM including the plurality of word lines WL and the select gate lines SGD and SGS described above.

As shown in FIG. 2, in each block region BLK interposed between a plurality of plate-like portions LI, a plurality of pillars PL are disposed in a periodic pattern. In the example of FIG. 2, the pillars PL are arranged in a staggered arrangement as viewed from above. Note that the pillar PL may have other periodic arrangements such as a grid arrangement.

In one block region BLK between the plate-like portions LI adjacent to each other in the Y direction, as described above, the separation layer SHE separating the select gate line SGD into a plurality of partitions extends in a direction along the X direction. Here, to maintain the periodic arrangement in the plurality of pillars PL, the separation layer SHE may overlap an arrangement of a part of pillars of the arrangement of the plurality of pillars PL extending in the direction along the X direction as viewed from above.

As such, it is possible to form each pillar PL with higher accuracy while minimizing processing errors in a process of manufacturing the semiconductor memory device 1 described below by maintaining the periodic arrangement in a plurality of pillars PL.

On both sides of each block region BLK in the X direction, as described above, the stepped regions SR (see FIG. 1B) are disposed. In the stepped region SR, only the contacts CC connected to each layer of the word line WL and the like are disposed. Therefore, in an extra space generated in the stepped region SR, dummy pillars (not shown) following the periodic arrangement of the above-described plurality of pillars PL are disposed. As a result, also in both end portions of the memory region MR in the X direction, it is possible to form each pillar PL with higher accuracy while minimizing processing errors.

Meanwhile, in an end portion of the stacked body LM in the Y direction, a dummy block region BLKd is disposed. The dummy block region BLKd is disposed adjacent to the outside in the Y direction of a plurality of block regions BLK arranged in the Y direction, and is a region between a dummy plate-like portion LId on the outside in the Y direction and the plate-like portion LI adjacent to the dummy plate-like portion LId in the Y direction.

That is, the dummy plate-like portion LId is disposed on the outermost side in the Y direction among a plurality of plate-like portions LI and LId. One of differences between the dummy plate-like portion LId and the above-described plurality of plate-like portions LI is that bridge portions BR and BRw in upper end portions of the plate-like portions LI and LId, respectively, have different shapes.

A plurality of bridge portions BR are arranged along the X direction at predetermined intervals in the upper end portions of the plurality of plate-like portions LI, respectively. As shown in the example of FIG. 2, the plurality of bridge portions BR provided in each of the plate-like portions LI may be arranged to be substantially at the same position in the X direction and may be arranged in the Y direction between the plurality of plate-like portions LI. Alternatively, the bridge portions BR may be arranged to be at different positions in the X direction between the plurality of plate-like portions LI and may not be arranged in the Y direction.

In the dummy block region BLKd, a plurality of dummy pillars PLd are disposed instead of the above-described plurality of pillars PL. The dummy pillars PLd do not contribute to the function of the semiconductor memory device 1, and are provided in both end portions of the stacked body LM in the Y direction to prevent characteristic fluctuation of the memory cells in both end portions of the stacked body LM in the Y direction. A region between the plate-like portions LI and LId where the pillars PLd are disposed also serves as the dummy block region BLKd that does not contribute to the function of the semiconductor memory device 1.

The arrangement of the pillars PLd in the dummy block region BLKd follows the periodic arrangement of the pillars PL in the block region BLK described above. That is, in the example of FIG. 2, the dummy pillars PLd are also arranged in a staggered arrangement, and the arrangement of a part of pillars PLd may overlap the separation layer SHE to maintain the periodicity of the arrangement of the pillars PLd.

As such, by providing the dummy pillars PLd, it is possible to form the plurality of pillars PL that contribute to the function of the semiconductor memory device 1 in both end portions in the Y direction with higher accuracy while minimizing processing errors.

Further outside the plate-like portion LId from a predetermined position between the plate-like portions LI and LId in the Y direction, the stacked body LM serves as a stacked body LMs in which a plurality of sacrifice layers are stacked instead of the plurality of word lines WL and the like in the stacked body LM. A dummy stepped region SRd is disposed further outside the plate-like portion LId in the Y direction, and each layer of the stacked body LMs is processed into a stepped shape extending in the Y direction and terminated.

As described below, the dummy stepped region SRd is a stepped region collaterally formed when forming the stepped region SR in manufacturing of the semiconductor memory device 1. Therefore, the stepped region SRd has no function as a lead region of the word line WL unlike the above-described stepped region SR (see FIG. 1B) disposed on both sides of the stacked body LM in the X direction, and the contacts CC and the like are not disposed. Since the stepped region SRd is an invalid region that does not contribute to the function of the semiconductor memory device 1, an area of the stepped region SRd occupied in the semiconductor memory device 1 is reduced compared to the stepped region SR.

Though not shown in FIG. 2, the dummy stepped region SRd and the outside of the stepped region SRd in the Y direction are also covered with the above-described insulating layer 50 (see FIG. 1A).

FIGS. 3A to 3D are cross-sectional views showing the structure of the semiconductor memory device 1.

More specifically, FIGS. 3A and 3B are cross-sectional views of the memory region MR of the semiconductor memory device 1 along the Y direction. Here, FIG. 3A shows a cross section of the above-described block region BLK, and FIG. 3B shows a cross section of the above-described dummy block region BLKd. In FIGS. 3A and 3B, a structure below the insulating layer 60 and a structure above an insulating layer 53 described below are omitted.

FIG. 3C is an enlarged cross-sectional view of the pillar PL at a height position of the select gate lines SGD and SGS. FIG. 3D is an enlarged cross-sectional view of the pillar PL at a height position of the word line WL.

As shown in FIG. 3A, in the block region BLK, the source line SL has a multilayer structure in which, for example, a lower source line DSLa, an intermediate source line BSL, and an upper source line DSLb are stacked in this order on the insulating layer 60. The lower source line DSLa, the intermediate source line BSL, and the upper source line DSLb are, for example, a polysilicon layer. Here, at least the intermediate source line BSL may be a conductive polysilicon layer or the like in which impurities are diffused.

The source line SL is connected to the peripheral circuit CBA via the electrode film EL by a through-contact (not shown) extending from the electrode film EL to the peripheral circuit CBA in the above-described insulating layer 50 outside the stacked body LM.

The stacked body LM is disposed on the source line SL. The stacked body LM includes stacked bodies LMa and LMb in which a plurality of word lines WL and a plurality of insulating layers OL are alternately stacked one by one.

The stacked body LMa is disposed above the source line SL. Further below the lowermost word line WL of the stacked body LMa, a plurality of select gate lines SGS0 and SGS1 are disposed via the insulating layer OL in this order from an upper layer side of the stacked body LMa. The stacked body LMb is disposed on the stacked body LMa. Above the uppermost word line WL of the stacked body LMb, a plurality of select gate lines SGD0 and SGD1 are disposed via the insulating layer OL in this order from an upper layer side of the stacked body LMb.

The number of word lines WL and select gate lines SGD and SGS stacked in the stacked body LM is freely selected. The word lines WL and the select gate lines SGD and SGS are, for example, a tungsten layer or a molybdenum layer. The insulating layer OL is, for example, a silicon oxide layer.

An upper surface of the stacked body LM is covered with an insulating layer 52. The insulating layer 52 is covered with the insulating layer 53. Each of the insulating layers 52 and 53 corresponds to a portion of the insulating layer 50 of FIGS. 1A and 1B.

As described above, the stacked body LM is divided in the Y direction by the plurality of plate-like portions LI. That is, the plate-like portions LI are arranged in the Y direction and extend in a direction along the stacking direction of the stacked body LM and the X direction.

As such, the plate-like portion LI continuously extends in the stacked body LM from one end portion to the other end portion of the stacked body LM in the X direction. The plate-like portion LI penetrates the stacked body LM and the upper source line DSLb, and reaches the intermediate source line BSL.

The plate-like portion LI has, for example, a tapered shape in which a width in the Y direction becomes smaller from an upper end portion toward a lower end portion. Alternatively, the plate-like portion LI has, for example, a bowing shape in which a width in the Y direction is maximized at a predetermined position between the upper end portion and the lower end portion.

Each of the plate-like portions LI includes an insulating layer 54, a conductive layer 24, and the bridge portions BR. The insulating layer 54 is, for example, a silicon oxide layer. The conductive layer 24 is, for example, a tungsten layer or a conductive polysilicon layer. The bridge portion BR is, for example, a silicon oxide layer similarly to the insulating layer 54. The bridge portion BR may be a polysilicon layer or the like.

The insulating layer 54 covers side walls of the plate-like portion LI facing each other in the Y direction. The conductive layer 24 is filled inside the insulating layer 54. As shown in FIG. 2 described above, the bridge portion BR covers a portion of an upper end portion of the conductive layer 24 in the plate-like portion LI extending in the direction along the X direction.

In the example of FIG. 2 described above, the bridge portions BR are arranged in the Y direction between the plurality of plate-like portions LI, but in FIG. 3A, to show each of the plate-like portion LI in a portion provided with the bridge portion BR and the plate-like portion LI in a portion without the bridge portion BR, respectively, a cross section of the plate-like portion LI in the portion provided with the bridge portion BR is shown on a left side of the drawing, and a cross section of the plate-like portion LI in the portion without the bridge portion BR is shown on a right side of the drawing.

A plurality of separation layers SHE penetrating an upper layer portion of the stacked body LMb and extending in the direction along the X direction are disposed between the plate-like portions LI adjacent to each other in the Y direction. The separation layers SHE are insulating layers 56 such as silicon oxide layers penetrating the select gate lines SGD0 and SGD1 and reaching the insulating layer OL directly below the select gate line SGD1.

In other words, the separation layers SHE penetrating the upper layer portion of the stacked body LMb extend in the memory region MR and a portion of the stepped region SR in the X direction between the plate-like portions LI so that the upper layer portion of the stacked body LMb is partitioned into the above-described select gate lines SGD0 and SGD1.

In the memory region MR, the plurality of pillars PL penetrating the stacked body LM, the upper source line DSLb, and the intermediate source line BSL and reaching the lower source line DSLa are disposed to be distributed. Each pillar PL has a shape such as a circular shape, an elliptical shape, or an oval shape as a cross sectional shape in a direction along the layer direction of the stacked body LM, that is, a direction along an XY plane.

The pillar PL has a tapered shape in which a diameter and a cross-sectional area become smaller from the upper layer side toward the lower layer side in a portion penetrating the stacked body LMa and a portion penetrating the stacked body LMb. Alternatively, the pillar PL has a bowing shape in which a diameter and a cross-sectional area are maximized at a predetermined position between the upper layer side and the lower layer side, for example, in the portion penetrating the stacked body LMa and the portion penetrating the stacked body LMb.

Each of the plurality of pillars PL includes a memory layer ME extending in the stacked body LM in the stacking direction, a channel layer CN penetrating the stacked body LM and connected to the intermediate source line BSL, a cap layer CP covering an upper surface of the channel layer CN, and a core layer CR serving as a core material of the pillar PL.

More specifically, the channel layer CN is in direct contact with the intermediate source line BSL at a depth position of the intermediate source line BSL. That is, the memory layer ME is disposed on a side surface of the pillar PL excluding the depth position of the intermediate source line BSL. The memory layer ME is also disposed on a bottom surface of the pillar PL reaching a depth of the lower source line DSLa.

As described above, the channel layer CN penetrates the stacked body LM, the upper source line DSLb, and the intermediate source line BSL inside the memory layer ME, reaches the depth of the lower source line DSLa, and is in contact with the intermediate source line BSL on the side surface. As a result, the channel layer CN is electrically connected to the source line SL including the intermediate source line BSL.

The cap layer CP is disposed in an upper end portion of the pillar PL to cover at least an upper end portion of the channel layer CN and is connected to the channel layer CN. The cap layer CP is connected to a bit line BL disposed in the insulating layer 53 via a plug CH disposed in the insulating layer 52. The bit line BL extends above the stacked body LM in a direction along the Y direction to intersect a lead direction of the word line WL.

In FIG. 3A, the separation layer SHE is disposed between a plurality of pillars PL adjacent to each other in the Y direction. As shown in the example of FIG. 2, the separation layer SHE may be disposed to overlap a part of pillars PL in the stacking direction of the stacked body LM. Then, since the separation layer SHE penetrates the upper end portion of the pillar PL to the height position of the select gate line SGD, the pillar PL may serve as a dummy pillar.

In FIG. 3A, the plugs CH are connected to only three pillars PL each penetrating three separated select gate lines SGD and electrically connected to the bit line BL shown in FIG. 3A, among six pillars PL. Other pillars PL are connected to other bit lines BL extending in the direction along the Y direction in parallel to the bit line BL shown in FIG. 3A at positions different from the cross section shown in FIG. 3A via the plugs CH not shown in FIG. 3A.

As shown in FIGS. 3C and 3D, the memory layer ME has a stacked structure including a block insulating layer BK, a tunnel insulating layer TN, and a charge storage layer CT.

The block insulating layer BK and the tunnel insulating layer TN of the memory layer ME and the core layer CR are, for example, a silicon oxide layer. The charge storage layer CT is, for example, a silicon nitride layer. The channel layer CN and the cap layer CP are, for example, a semiconductor layer such as a polysilicon layer or an amorphous silicon layer.

As shown in FIG. 3D, according to the structure described above, the memory cell MC is formed in portions of the side surface of the pillar PL facing each word line WL. A predetermined voltage is applied from the word line WL to write and read data to and from the memory cell MC.

As shown in FIG. 3C, select gates STD are formed in portions where the side surface of the pillar PL faces each of the select gate lines SGD0 and SGD1 in upper layers of the word line WL. Select gates STS are formed in portions where the side surface of the pillar PL faces each of the select gate lines SGS0 and SGS1 in lower layers of the word line WL.

Predetermined voltages are applied from each of the select gate lines SGD and SGS to turn on or turn off the select gates STD and STS, and the memory cells MC of the pillars PL to which the select gates STD and STS belong are brought into a selected state or a non-selected state.

As shown in FIG. 3B, the dummy block region BLKd is disposed between the plate-like portion LI disposed on a side of the block region BLK adjacent to the block region BLKd in the Y direction and the dummy plate-like portion LId separating a region where the above-described dummy stepped region SRd and the like are disposed from the block region BLKd outside the block region BLKd in the Y direction.

In a region outside the dummy block region BLKd in the Y direction, that is, in a region on a right side of the paper of the dummy plate-like portion LId, an intermediate sacrifice layer SCN is disposed instead of the intermediate source line BSL of the source line SL.

That is, in the block region BLKd, the lower source line DSLa, the intermediate sacrifice layer SCN, and the upper source line DSLb are disposed in order from the insulating layer 60 side corresponding to the lower source line DSLa, the intermediate source line BSL, and the upper source line DSLb disposed in the block region BLKd.

The intermediate sacrifice layer SCN is, for example, a silicon nitride layer and functions as a sacrifice layer when forming the intermediate source line BSL in the block region BLK in a process of manufacturing the semiconductor memory device 1 described below. In the block region BLKd, the intermediate source line BSL is not formed from the intermediate sacrifice layer SCN, and the intermediate sacrifice layer SCN that is a sacrifice layer remains as it is.

In the block region BLKd, the plurality of word lines WL and the select gate lines SGD and SGS are stacked above the upper source line DSLb, and the stacked body LMs in which a plurality of insulating layers NL are stacked and including stacked body LMsa and LMsb is disposed instead of the stacked body LM including the stacked bodies LMa and LMb.

That is, the stacked body LMs includes the stacked bodies LMsa and LMsb in which the plurality of insulating layers NL and the plurality of insulating layers OL are alternately stacked one by one. The stacked body LMsa corresponds to the stacked body LMa of the block region BLK and is disposed above the upper source line DSLb. The stacked body LMsb corresponds to the stacked body LMb of the block region BLK and is disposed on the stacked body LMsa.

The plurality of insulating layers NL provided in the stacked bodies LMsa and LMsb are, for example, a silicon nitride layer and function as sacrifice layers when forming the word lines WL and the like of the stacked body LM in the process of manufacturing the semiconductor memory device 1 described below. In the block region BLKd, the word lines WL and the like are not formed from the insulating layer NL, and the insulating layer NL that is a sacrifice layer remain as it is.

The number of layers of the plurality of insulating layers NL provided in the stacked body LMsa is equal to the total number of layers of the plurality of word lines WL and the select gate lines SGS provided in the stacked body LMa of the block region BLK. The number of layers of the plurality of insulating layers NL provided in the stacked body LMsb is equal to the total number of layers of the plurality of word lines WL and the select gate lines SGD provided in the stacked body LMb of the block region BLK. The insulating layers 52 and 53 covering the upper surface of the stacked body LM also cover an upper surface of the stacked body LMs.

The stacked body LMs and the intermediate sacrifice layer SCN interposed between the lower source line DSLa and the upper source line DSLb formed as above may also be disposed in a partial region in the block region BLKd. That is, as shown in FIG. 2 described above, the stacked body LMs and the intermediate sacrifice layer SCN are disposed on both sides in the Y direction with the dummy plate-like portion LId interposed therebetween.

Accordingly, in the dummy block region BLKd, the stacked body LM and the intermediate source line BSL may be disposed in a range of a predetermined distance in the Y direction from the plate-like portion LI on one side in the Y direction, and the stacked body LMs and the intermediate sacrifice layer SCN may be disposed in a range of a predetermined distance in the Y direction from the plate-like portion LId on the other side in the Y direction.

Here, the stacked body LM and the stacked body LMs may not have a clear boundary, and metal atoms such as tungsten contained in the word line WL of the stacked body LM may be gradually replaced by molecules such as silicon nitride contained in the insulating layer NL of the stacked body LMs to gradually replace the stacked body LM by the stacked body LMs.

The intermediate source line BSL and the intermediate sacrifice layer SCN may also not have a clear boundary, and atoms such as silicon contained in the intermediate source line BSL may be gradually replaced by molecules such as silicon nitride contained in the intermediate sacrifice layer SCN to gradually replace the intermediate source line BSL by the intermediate sacrifice layer SCN.

The stacked body LM and the intermediate source line BSL may occupy a region about at least half of the block region BLKd. In the block region BLKd, a volume occupied by the stacked body LM and the intermediate source line BSL may vary under conditions and the like in the process of manufacturing the semiconductor memory device 1 described below. Accordingly, the stacked body LM and the intermediate source line BSL may occupy a volume half or more of the block region BLKd or may occupy all of the block region BLKd.

In the example of FIG. 3B, the boundary between the stacked body LM and the stacked body LMs and the boundary between the intermediate source line BSL and the intermediate sacrifice layer SCN are at substantially identical positions from the plate-like portion LI on one side of the block region BLKd. The boundaries may be positioned to have different distances from the plate-like portion LI on one side of the block region BLKd. As an example, a distance of the boundary between the stacked body LM and the stacked body LMs from the plate-like portion LI may be shorter than a distance of the boundary between the intermediate source line BSL and the intermediate sacrifice layer SCN from the plate-like portion LI.

The dummy plate-like portion LId is disposed on one side of the block region BLKd in the Y direction and continuously extends in the stacked body LMs in the direction along the stacking direction of the stacked body LMs and the X direction from one end portion to the other end portion of the stacked body LMs in the X direction. The plate-like portion LId penetrates the stacked body LMs and the upper source line DSLb and reaches the intermediate sacrifice layer SCN.

The plate-like portion LId has a tapered shape in which, for example, a width in the Y direction becomes smaller from an upper end portion toward a lower end portion. Alternatively, the plate-like portion LId has a bowing shape in which, for example, the width in the Y direction is maximized at a predetermined position between the upper end portion and the lower end portion.

The plate-like portion LId includes the insulating layer 54, a sacrifice layer 25, and a bridge portion BRw. The sacrifice layer 25 is, for example, an amorphous silicon layer and functions as a sacrifice layer until the conductive layer 24 is formed in the plate-like portion LI in the process of manufacturing the semiconductor memory device 1 described below. In the plate-like portion LId, the conductive layer 24 is not formed, and the sacrifice layer 25 remains as it is. The bridge portion BRw is, for example, a silicon oxide layer similarly to the insulating layer 54 and the bridge portion BR of the plate-like portion LI. The bridge portion BRw may be a polysilicon layer or the like.

The insulating layer 54 covers side walls of the plate-like portion LId facing each other in the Y direction. The sacrifice layer 25 is filled inside the insulating layer 54. As shown in FIG. 2 described above, the bridge portion BRw covers all of an upper end portion of the sacrifice layer 25 in the plate-like portion LId that extends in the direction along the X direction.

Also in the dummy block region BLKd, a plurality of separation layers SHE penetrating an upper layer portion of the stacked body LMsb and extending in the direction along the X direction are disposed between the plate-like portions LI and LId adjacent to each other in the Y direction. A penetration depth of the separation layer SHE in the block region BLKd corresponds to the depth of the select gate line SGD in the block region BLK.

In the block region BLKd, the plurality of dummy pillars PLd penetrating the stacked body LM or the stacked body LMs, the upper source line DSLb, and the intermediate source line BSL or the intermediate sacrifice layer SCN, and reaching the lower source line DSLa are disposed to be distributed.

Each pillar PLd has a structure similar to that of the above-described pillar PL. That is, each of the plurality of pillars PLd includes a dummy layer MEd extending in the stacked body LM or the stacked body LMs in the stacking direction, a dummy layer CNd penetrating the stacked body LM or the stacked body LMs, a dummy layer CPd covering an upper surface of the dummy layer CNd, and a dummy layer CRd serving as a core material of the pillar PLd.

In the pillar PLd disposed in the stacked body LM, the dummy layer CNd penetrates the stacked body LM and is in direct contact with the intermediate source line BSL at the depth position of the intermediate source line BSL. Meanwhile, in the pillar PLd disposed in the stacked body LMs, the dummy layer MEd is disposed around the dummy layer CNd penetrating the stacked body LMs, and the dummy layer CNd and the intermediate sacrifice layer SCN are not in direct contact with each other. In both cases, the dummy layer MEd is disposed on a bottom surface of the pillar PLd reaching the depth of the lower source line DSLa.

The dummy layer CPd is disposed in an upper end portion of the pillar PLd to cover at least an upper end portion of the dummy layer CNd and is connected to the dummy layer CNd. The dummy layer CPd is connected to a dummy bit line BLd disposed in the insulating layer 53 via a dummy plug CHd disposed in the insulating layer 52.

While the bit line BL connected to the pillar PL in the block region BLK via the plug CH is electrically connected to the peripheral circuit CBA, the bit line BLd connected to the dummy pillar PLd in the block region BLKd is not connected to the peripheral circuit CBA. It is because the dummy pillar PLd does not contribute to the function of the semiconductor memory device 1 and does not need to be electrically operated.

### Method for Manufacturing Semiconductor Memory Device

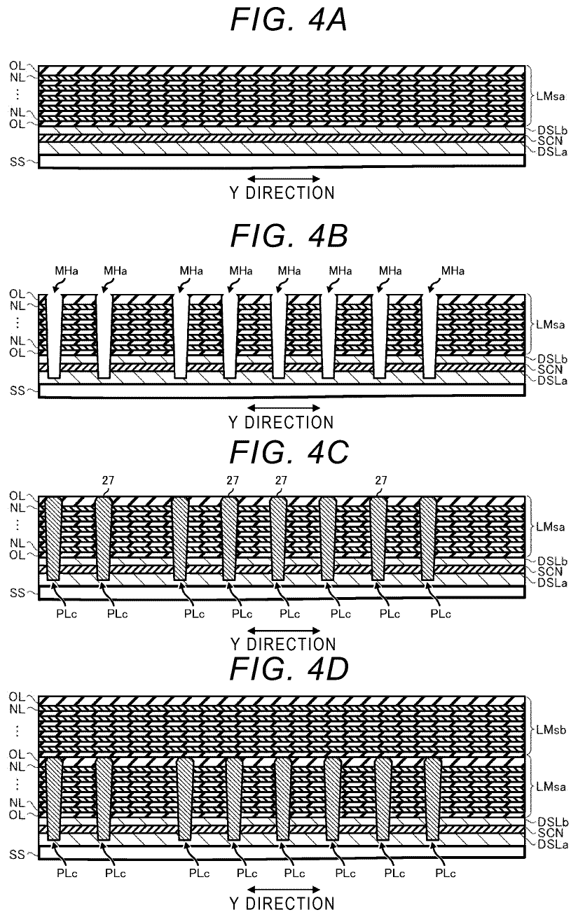

Next, a method for manufacturing the semiconductor memory device 1 will be described with reference to FIGS. 4A to 9C. FIGS. 4A to 9C are diagrams illustrating a part of the method for manufacturing the semiconductor memory device 1. In FIGS. 4A to 9C, a cross section along the Y direction of a region to be the memory region MR is shown.

As shown in FIG. 4A, the lower source line DSLa, the intermediate sacrifice layer SCN, and the upper source line DSLb are formed on a supporting substrate SS in this order.

As the supporting substrate SS, a semiconductor substrate such as a silicon substrate, an insulating substrate such as a ceramic substrate, a conductive substrate, or the like can be used. On an upper surface side of the supporting substrate SS, the above-described insulating layer 60 (see FIG. 2 and the like) may be formed. The intermediate sacrifice layer SCN is, for example, a silicon nitride layer, and as described above, is a layer replaced by a polysilicon layer or the like later to be the intermediate source line BSL.

On the upper source line DSLb, the stacked body LMsa in which the plurality of insulating layers NL and the plurality of insulating layers OL are alternately stacked one by one is formed. The insulating layer NL is, for example, a silicon nitride layer, and as described above, functions as a sacrifice layer replaced by a conductive material later to be the word line WL or the select gate line SGS.

Thereafter, though not shown, the insulating layer NL and the insulating layer OL are processed into a stepped shape in both end portions of the stacked body LMsa in the X direction. Such processing can be performed by repeating slimming of a mask pattern such as a photoresist layer and etching of the insulating layer NL and the insulating layer OL of the stacked body LMsa multiple times.

That is, the mask pattern is formed on an upper surface of the stacked body LMsa, and the insulating layer NL and the insulating layer OL of exposed portions are etched and removed one by one. By treatment using oxygen plasma or the like, an end portion of the mask pattern is retreated to newly expose the upper surface of the stacked body LMsa, and the insulating layer NL and the insulating layer OL are further etched and removed one by one. By repeating such treatment multiple times, the stacked body LMsa having a stepped shape in both end portions in the X direction is formed.

Here, both end portions of the stacked body LMsa in the Y direction are also processed into a stepped shape, and a structure to be the dummy stepped region SRd later is formed. Thereafter, stepped structures in both end portions in the X direction and both end portions in the Y direction are covered with the above-described insulating layer 50 (see FIG. 1A).

As shown in FIG. 4B, a plurality of memory holes MHa extending in the stacked body LMsa in the stacking direction are formed. The plurality of memory holes MHa penetrate the stacked body LMsa, the upper source line DSLb, and the intermediate sacrifice layer SCN, and reach the lower source line DSLa. The memory holes MHa are a portion to be a lower structure of the pillar PL or the pillar PLd later.

The memory holes MHa have two portions widely spaced on the paper, and the plate-like portions LI and LId are provided in the two portions later. Accordingly, two memory holes MHa on the left side of the paper are portions to be the lower structure of the pillar PL, and six memory holes MHa at the center of the paper are portions to be the lower structure of the pillar PLd.

As shown in FIG. 4C, the memory holes MHa are filled with a sacrifice layer 27 such as an amorphous silicon layer or a CVD-carbon layer. As a result, pillars PLc that are the plurality of memory holes MHa filled with the sacrifice layer 27 are formed.

As shown in FIG. 4D, the stacked body LMsb covering the stacked body LMsa and in which the plurality of insulating layers NL and the plurality of insulating layers OL are alternately stacked one by one is formed. The insulating layer NL of the stacked body LMsb functions as a sacrifice layer replaced by a conductive layer later to be the word line WL or the select gate line SGD.

Thereafter, though not shown, in a partial region of the stacked body LMsb, the insulating layer NL and the insulating layer OL are processed into a stepped shape. Such processing can be performed by repeating slimming of a mask pattern such as a photoresist layer and etching of the insulating layer NL and the insulating layer OL of the stacked body LMsb multiple times similarly to the processing on the stacked body LMsa described above.

Here, an uppermost end of a stepped portion formed in the stacked body LMsa and a lowermost end of a stepped portion formed in the stacked body LMsb are arranged close to each other, and a stepped shape is formed to be continuous from a lower layer side of the stacked body LMsa to an upper layer side of the stacked body LMsb. As a result, in the stacked bodies LMsa and LMsb, a stepped region SR having a stepped shape from the stacked body LMsa to the stacked body LMsb is formed in both end portions in the X direction.

Here, both end portions of the stacked body LMsb in the Y direction are processed into a stepped shape similarly, and a structure to be a portion of the dummy stepped region SRd is formed. Thereafter, stepped structures of the stacked body LMsb in both end portions in the X direction and both end portions in the Y direction are covered with the above-described insulating layer 50 (see FIG. 1A).

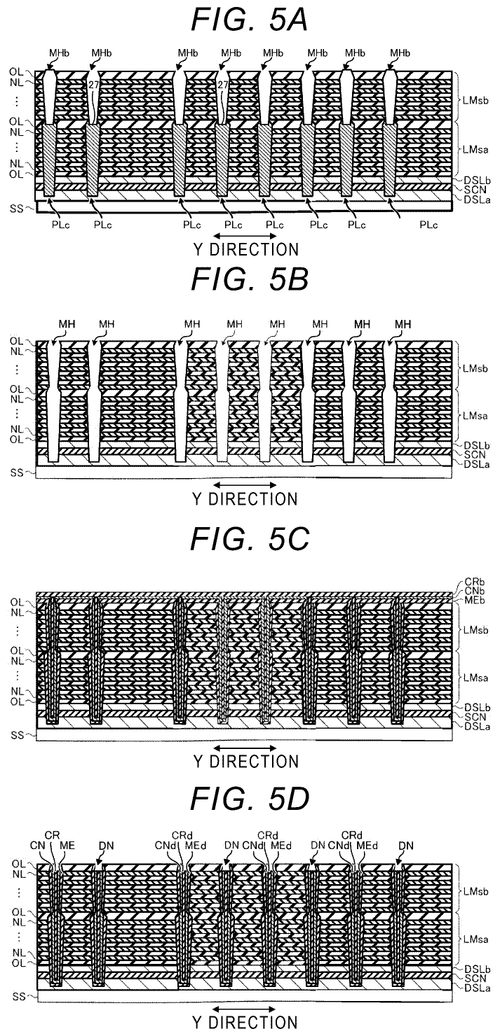

As shown in FIG. 5A, a plurality of memory holes MHb penetrating the stacked body LMsb and each connected to each of the plurality of pillars PLc formed in the stacked body LMsa are formed. The memory holes MHb are portions to be an upper structure of the pillar PL or the pillar PLd later.

As shown in FIG. 5B, the sacrifice layer 27 is removed from the pillars PLc at the bottom of the memory holes MHb. As a result, the memory holes MHa are opened at the bottom of the plurality of memory holes MHb, and a plurality of memory holes MH penetrating the stacked bodies LMsb and LMsa, the upper source line DSLb, and the intermediate sacrifice layer SCN, and reaching the lower source line DSLa are formed.

Two memory holes MH on the left side of the paper are structures to be the pillar PL, and six memory holes MH at the center of the paper are structures to be the pillar PLd.

When the sacrifice layer 27 filling in the pillars PLc is a CVD-carbon layer or the like, the sacrifice layer 27 may be collectively removed from the pillars PLc while the mask pattern and the like used in forming the memory holes MHb in FIG. 5A described above are removed by ashing or the like using oxygen plasma.

As shown in FIG. 5C, in the memory hole MH, a multilayer insulating layer MEb, a semiconductor layer CNb, and an insulating layer CRb are formed in this order. As a result, the multilayer insulating layer MEb and the semiconductor layer CNb are formed on the side surface of the memory hole MH and a bottom surface where the lower source line DSLa is exposed, and a center portion of the memory hole MH is filled with the insulating layer CRb. The multilayer insulating layer MEb, the semiconductor layer CNb, and the insulating layer CRb are layers corresponding to each of the memory layer ME, the channel layer CN, or each of the core layer CR or the dummy layers CRd, CNd, and MEd. The multilayer insulating layer MEb, the semiconductor layer CNb, and the insulating layer CRb are also formed on an upper surface of the stacked body LMsb in this order.

As shown in FIG. 5D, the insulating layer CRb, the semiconductor layer CNb, and the multilayer insulating layer MEb on the upper surface of the stacked body LMsb are sequentially removed, and the layers are separated in each memory hole MH. As a result, the core layer CR, the channel layer CN, and the memory layer ME are formed in the memory holes MH on the left side of the paper to be the pillars PL. The dummy layers CRd, CNd, and MEd are formed in the memory holes MH at the center of the paper to be the pillars PLd.

In removing the insulating layer CRb, the semiconductor layer CNb, and the multilayer insulating layer MEb on the upper surface of the stacked body LMsb, upper end portions of the core layer CR and the channel layer CN and upper end portions of the dummy layers CRd and CNd are retreated from an upper surface of the memory hole MH to form a depression DN in an upper end portion of the memory hole MH.

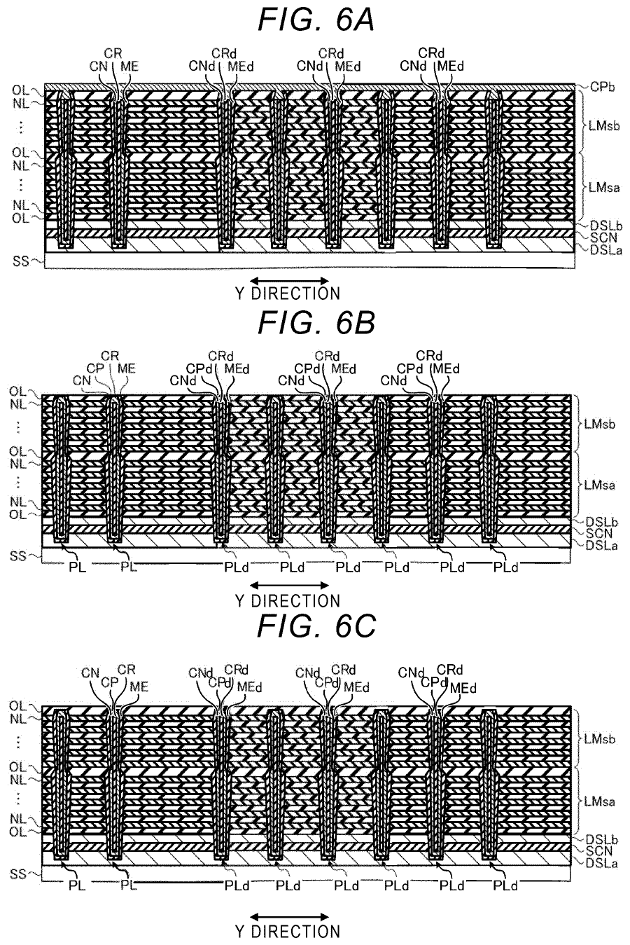

As shown in FIG. 6A, a semiconductor layer CPb is formed in the depression DN in the upper end portion of the memory hole MH. The semiconductor layer CPb is a layer to be the cap layer CP or the dummy layer CPd, and is also formed on the upper surface of the stacked body LMsb.

As shown in FIG. 6B, the semiconductor layer CPb on the upper surface of the stacked body LMsb is removed by chemical mechanical polishing (CMP) or the like to form the cap layer CP or the dummy layer CPd disposed in the upper end portion of the memory hole MH. Here, the uppermost insulating layer OL of the stacked body LMsb is also removed by a predetermined layer thickness.

As shown in FIG. 6C, the uppermost insulating layer OL of the stacked body LMsb thinned by CMP or the like is stacked. As a result, the pillar PL in which the cap layer CP is buried in the uppermost insulating layer OL and the pillar PLd in which the dummy layer CPd is buried in the uppermost insulating layer OL are formed.

Here, the memory layer ME covers the entire side wall of the pillar PL, and a portion of the side surface of the channel layer CN is not exposed from the memory layer ME. The same applies to the dummy pillar PLd.

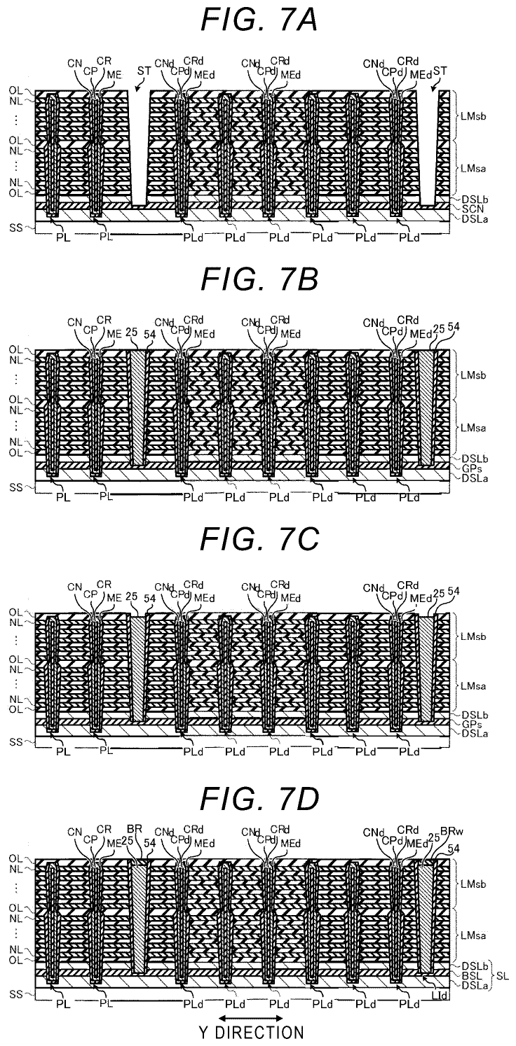

As shown in FIG. 7A, slits ST penetrating the stacked bodies LMsb and LMsa and the upper source line DSLb, and reaching the intermediate sacrifice layer SCN are formed. The slits ST also extend in the stacked bodies LMsa and LMsb in the direction along the X direction.

As shown in FIG. 7B, the insulating layer 54 is formed on the side walls of the slits ST facing each other in the Y direction. The sacrifice layer 25 such as an amorphous silicon layer is filled in the insulating layer 54 covering the side wall of the slit ST.

As shown in FIG. 7C, an upper end portion of the sacrifice layer 25 filled in the slit ST is removed. Here, in the slit ST to be the plate-like portion LI such as the slit ST on the left side of the paper, a portion of the sacrifice layer 25 in the slit ST extending in the direction along the X direction is intermittently removed. Meanwhile, in the slit ST on the right side of the paper to be the plate-like portion LId, all of the upper end portion of the sacrifice layer 25 extending in the direction along the X direction is removed.

As shown in FIG. 7D, a silicon oxide layer, a polysilicon layer, or the like covering a portion where the sacrifice layer 25 in the upper end portion of the slit ST is removed is formed. As a result, the bridge portion BR is formed in the slit ST and the like on the left side of the paper, and the bridge portion BRw is formed in the slit ST on the right side of the paper. Accordingly, the dummy plate-like portion LId including the insulating layer 54, the sacrifice layer 25, and the bridge portion BRw is formed on the right side of the paper.

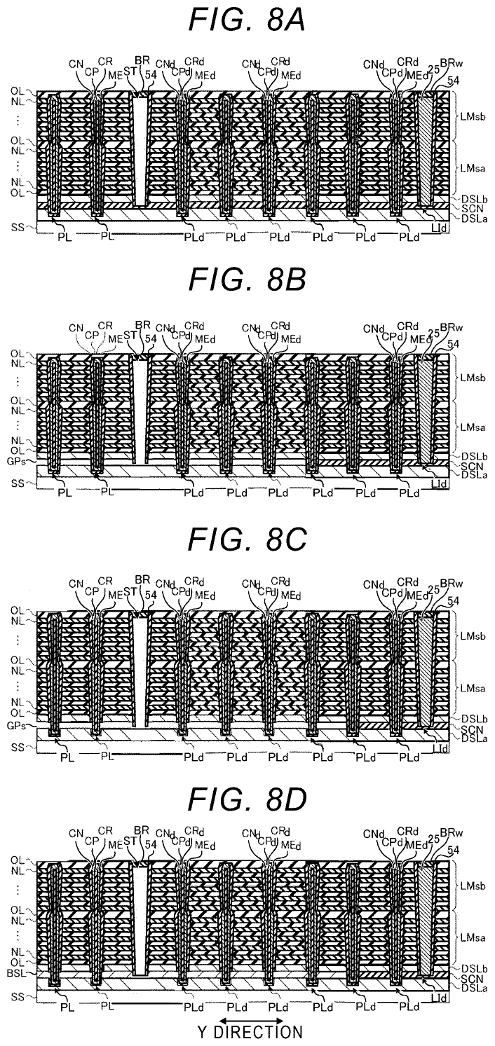

As shown in FIG. 8A, the sacrifice layer in the slit ST is removed from openings between the bridge portions BR intermittently formed in the upper end portion of each of the plurality of slits ST including the slit ST on the left side of the paper. Here, in the plate-like portion LId on the right side of the paper, the bridge portion BRw covering the entire upper surface thereof is formed. Therefore, the sacrifice layer 25 is not removed from the plate-like portion LId.

As shown in FIG. 8B, for example, a removal solution for the intermediate sacrifice layer SCN such as hot phosphoric acid is poured via the plurality of slits ST such as the slit ST on the left side of the paper in which the sacrifice layer 25 is removed and the side wall is protected by the insulating layer 54, thereby removing the intermediate sacrifice layer SCN interposed between the lower source line DSLa and the upper source line DSLb. Since the side walls of the slits ST are protected by the insulating layer 54, removal of the insulating layer NL in the stacked bodies LMsa and LMsb is prevented.

As a result, a gap layer GPs is formed between the lower source line DSLa and the upper source line DSLb. A portion of the memory layer ME in an outer peripheral portion of the pillar PL is exposed in the gap layer GPs.

Here, a treatment time using the removal solution such as hot phosphoric acid is determined based on a time necessary for removing the entire intermediate sacrifice layer SCN in a region corresponding to one block region BLK when the removal solution is poured from both sides in the Y direction using the slits ST adjacent to each other in the Y direction.

Meanwhile, since the sacrifice layer 25 is still filled in the plate-like portion LId on the right side of the paper, the above-described removal solution is not poured from the plate-like portion LId. Accordingly, in a region where the six pillars PLd at the center of the paper are disposed, removal treatment of the intermediate sacrifice layer SCN is proceeded only from the slit ST on the left side of the paper, and in a region close to the plate-like portion LId on the right side of the paper, the intermediate sacrifice layer SCN may remain unremoved.

Here, in a part of pillars PLd disposed close to the slit ST on the left side of the paper, the dummy layer MEd formed between the lower source line DSLa and the upper source line DSLb is exposed in the gap layer GPs, and in a part of pillars PLd disposed close to the plate-like portion LId on the right side of the paper, the dummy layer MEd remains covered with the intermediate sacrifice layer SCN.

As shown in FIG. 8C, a chemical solution is appropriately poured into the gap layer GPs via the plurality of slits ST to sequentially remove the block insulating layer BK, the charge storage layer CT, and the tunnel insulating layer TN (see FIGS. 3C and 3D) of the memory layer ME exposed in the gap layer GPs. As a result, the memory layer ME is removed from a portion of the side wall of the pillar PL, and a portion of the inner channel layer CN is exposed in the gap layer GPs.

Here, in the region where the six pillars PLd in the center portion of the paper are disposed, the dummy layers MEd of a part of pillars PLd in a region where the gap layer GPs is formed may be removed similarly to the above-described plurality of pillars PL, and the dummy layers CNd may be exposed in the gap layer GPs.

As shown in FIG. 8D, for example, raw material gas such as amorphous silicon is injected from the plurality of slits ST in which the side wall is protected by the insulating layer 54, and the gap layer GPs is filled with amorphous silicon or the like. The supporting substrate SS is heat-treated to change amorphous silicon filled in the gap layer GPs into a polycrystalline state and form the intermediate source line BSL containing polysilicon or the like.

As a result, a portion of the channel layer CN of the pillar PL is connected to the source line SL from the side surface via the intermediate source line BSL. Similarly, the exposed dummy layers CNd of a part of pillars PLd may be connected to the source line SL from the side surface via the intermediate source line BSL.

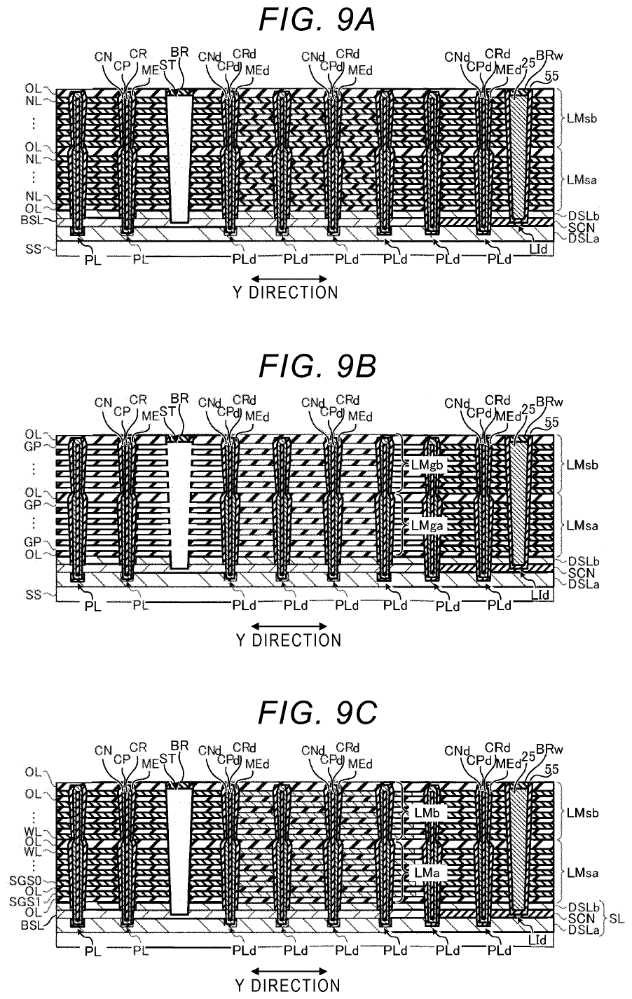

As shown in FIG. 9A, the insulating layer 54 on the side walls of the plurality of slits ST in which the sacrifice layer 25 is removed is once removed. Here, when the bridge portion BR is formed with a material such as polysilicon different from the insulating layer 54, it is also possible to prevent damage to the bridge portion BR in removing the insulating layer 54.

As shown in FIG. 9B, a removal solution for the insulating layer NL such as hot phosphoric acid is poured from the plurality of slits ST into the stacked bodies LMsa and LMsb to remove the insulating layer NL of the stacked bodies LMsa and LMsb.

Here, a treatment time of the removal solution such as hot phosphoric acid is determined based on a time necessary for removing the entire insulating layer NL in a region corresponding to one block region BLK when the removal solution is poured from both sides in the Y direction using the slits ST adjacent to each other in the Y direction.

Meanwhile, since the plate-like portion LId on the right side of the paper remains filled with the sacrifice layer 25, the above-described removal solution is not poured from the plate-like portion LId. Accordingly, in the region where the six pillars PLd at the center of the paper are disposed, removal treatment of the insulating layer NL is proceeded only from the slit ST on the left side of the paper, and in a region close to the plate-like portion LId on the right side of the paper, the insulating layer NL may remain unremoved.

Accordingly, in partial regions between a plurality of slits ST including the slit ST on the left side of the paper in which the sacrifice layer 25 is removed, and between the plate-like portion LId on the right side of the paper that remains filled with the sacrifice layer 25 and the slit ST on the left side of the paper in which the sacrifice layer 25 is removed, stacked bodies LMga and LMgb including a plurality of gap layers GP in which the insulating layer NL between the insulating layers OL is removed are formed.

The stacked bodies LMga and LMgb including the plurality of gap layers GP have a fragile structure. The plurality of pillars PL support the fragile stacked bodies LMga and LMgb. As a result, bending of the remaining insulating layer OL in the stacked bodies LMga and LMgb or distortion or collapsing of the stacked bodies LMga and LMgb is prevented.

The insulating layer 50 (see FIG. 1A) covering the dummy stepped regions SRd and the outside thereof in both end portions of the stacked bodies LMga and LMgb in the Y direction generates expansion stress (i.e., tensile stress) expanding from a center portion of the insulating layer 50 to the outside. Therefore, the stacked bodies LMga and LMgb receive contraction stress acting toward center portions of the stacked bodies LMga and LMgb in the Y direction.

As a result, the plurality of pillars PL formed in the stacked bodies LMga and LMgb may have a positional deviation in the Y direction. When positional deviation occurs in the plurality of pillars PL, misalignment with the plugs CH to be subsequently formed may occur, and connection failure between the pillars PL and the plugs CH may occur.

The plurality of slits ST may be crushed in the Y direction by contraction stress in the stacked bodies LMga and LMgb and may be reduced in width in the Y direction. As a result, the plurality of slits ST may be closed, and subsequent processing may be hindered. Deformation of the width of the slit ST may further promote positional deviation of the plurality of pillars PL in the Y direction.

Positional deviation as described above becomes more significant toward the end portions of the stacked body LM in the Y direction. Such positional deviation is one of reasons for disposing the dummy pillar PLd in the end portion of the stacked body LM. That is, in a region where positional deviation occurs due to the stress of the insulating layer 50, the dummy pillar PLd is disposed instead of the pillar PL contributing to the function of the semiconductor memory device 1.

In the semiconductor memory device 1, in addition to the above-described measure, the dummy plate-like portions LId are disposed in the end portions of the stacked bodies LMga and LMgb in the Y direction such that the stacked bodies LMsa and LMsb in which the insulating layer NL is not removed remains in the end portions of the stacked bodies LMga and LMgb in the Y direction. Accordingly, the stacked bodies LMga and LMgb disposed inside the stacked bodies LMsa and LMsb in the Y direction and the insulating layer 50 disposed on the outside in the Y direction are separated, and an influence of stress generated by the insulating layer 50 on the stacked bodies LMga and LMgb can be prevented.

Therefore, positional deviation of the pillars PL due to the contraction stress in the stacked bodies LMga and LMgb and deformation of the width of the slits ST are prevented.

Each of the plurality of slits ST includes the bridge portion BR in the upper end portion. As a result, stress on both sides of the slits ST in the Y direction is weakened, and deformation of the width of the slits ST is further prevented.

As shown in FIG. 9C, for example, raw material gas of a conductive material such as tungsten or molybdenum is injected from the slits ST into the stacked bodies LMga and LMgb, and the gap layers GP of the stacked bodies LMga and LMgb are filled with the conductive material to form the plurality of word lines WL and the like.

As a result, the stacked body LM including the stacked bodies LMa and LMb in which the plurality of word lines WL and the like and the plurality of insulating layers OL are alternately stacked one by one is formed. As described above, here, the stacked body LMs remains in partial regions in both end portions of the stacked body LM in the Y direction.

As above, the process of forming the intermediate source line BSL from the intermediate sacrifice layer SCN and the process of forming the word line WL from the insulating layer NL are also referred to as replacement process.

Thereafter, the insulating layer 54 is formed again on the side wall of the slit ST, and the conductive layer 24 is filled in the insulating layer 54 to form the plate-like portion LI.

A groove penetrating one or a plurality of conductive layers including the uppermost conductive layer of the stacked body LMb is formed, and the groove is filled with the insulating layer 56 to form the separation layer SHE that partitions the conductive layers into patterns of the select gate lines SGD.

The plurality of contacts CC reaching each of the word lines WL and the select gate lines SGD and SGS forming each step of the stepped structure of the stepped region SR from the upper side of the stepped region SR are formed.

The insulating layer 52 is formed on the upper surface of the stacked body LM, the plugs CH penetrating the insulating layer 52 and connected to each of the plurality of pillars PL are formed, and plugs connected to the contacts CC are formed. The insulating layer 53 is formed on the insulating layer 52, the bit line BL connected to the plugs CH is formed, and the upper layer wiring and the like connected to the contacts CC via the plugs of the contacts CC are formed. On the upper surface of the insulating layer 53, electrode pads and the like are formed for electrical connection with the peripheral circuit CBA.

In the above description, the plugs CH, the bit line Bl, and the like may be collectively formed using, for example, a dual damascene method.

Also for the dummy pillar PLd, formation of the dummy plug CHd, formation of the dummy bit line BLd, and the like are performed in parallel to the above-described processing.

Meanwhile, the peripheral circuit CBA is formed on the semiconductor substrate SB provided separately from the supporting substrate SS on which the stacked body LM is formed, and is covered with the insulating layer 40. In the insulating layer 40, contacts, vias, wiring, and the like leading out the peripheral circuit CBA to the surface of the insulating layer 40 are formed to be connected to electrode pads or the like formed on the upper surface of the insulating layer 40.

Subsequently, the supporting substrate SS and the semiconductor substrate SB are bonded to each other via the insulating layers 50 and 40, and the electrode pads in the insulating layers 50 and 40 are connected to each other. Thereafter, the supporting substrate SS is removed to expose the source line SL, and the electrode film EL is connected via the insulating layer 60 in which the plug PG is formed.

Accordingly, the semiconductor memory device 1 is manufactured.

### Overview

In a semiconductor memory device such as a three-dimensional nonvolatile memory, since periodic arrangement of pillars is terminated in both end portions of the stacked body in the Y direction, processing errors are likely to occur when forming the pillars. In both end portions of the stacked body in the Y direction, only the dummy stepped regions having a comparatively small area are disposed, and positional deviation of the pillars is likely to occur due to stress from the outside of the stacked body during replacement of the stacked body. Therefore, the pillars near both end portions of the stacked body in the Y direction are set as dummy pillars, and a region where the dummy pillars are disposed is set as a dummy block.

Considering influence of positional deviation in the pillars near both end portions of the stacked body in the Y direction, it is preferable that a plurality of dummy blocks are disposed in both end portions of the stacked body in the Y direction, respectively. However, as the area of the dummy blocks in the semiconductor memory device increases, it is difficult to achieve increase in storage capacity of the semiconductor memory device and reduction in size thereof.

According to the semiconductor memory device 1 described above, all of the upper end portions of the plate-like portions LId closest to the end portions of the stacked bodies LM and LMs in the Y direction is covered with the bridge portions BRw.

As such, by covering all of the plate-like portions LId in the end portions of the stacked bodies LM and LMs with the bridge portions BRw, it is possible to hinder replacement of the stacked body LMs near the end portions in the Y direction and prevent contraction stress acting on the stacked body LM formed inside the stacked body LMs in the Y direction.

As a result, a range from the positions of the end portions of the stacked bodies LM and LMs where positional deviation of the pillars PL may occur is reduced, for example, there is no need to dispose a plurality of dummy blocks, and it is possible to reduce the dummy block region BLKd.

Since two kinds of different plate-like portions LI and LId can be formed by changing a shape of the bridge portion BRw, it is possible to form the plate-like portion LI used for replacement of the stacked body LM and the like and the plate-like portion LId not contributing to the replacement of the stacked body LM and the like, without causing an increase in the number of procedures.

According to the semiconductor memory device 1, the plate-like portions LId disposed closest to the end portions of the stacked bodies LM and LMs in the Y direction are filled with the sacrifice layer 25. As such, when the sacrifice layer 25 remains in the plate-like portions LId in the end portions of the stacked bodies LM and LMs, it is possible to hinder replacement of the stacked body LMs near the end portions in the Y direction.

According to the semiconductor memory device 1, the semiconductor memory device 1 includes the stacked body LMs disposed outside the plate-like portion LId disposed closest to the end portion of the stacked bodies LM and LMs in the Y direction and in which the plurality of insulating layers NL, instead of the plurality of word lines WL and the like, and the plurality of insulating layers OL are alternately stacked one by one. As such, when the stacked body LMs remains in the end portion of the stacked body LM, it is possible to prevent contraction stress to the stacked body LM formed inside the stacked body LMs in the Y direction.

According to the semiconductor memory device 1, a plurality of pillars PL and PLd are selectively disposed in the region between the plate-like portions LId and LI and the region between the plate-like portions LI and LI among the region between the plate-like portion LId disposed closest to the end portion of the stacked bodies LM and LMs in the Y direction and the end portion of the stacked bodies LM and LMs in the Y direction, the region between the plate-like portion LI adjacent to the plate-like portion LId in the Y direction and the plate-like portion LId, and the region between the plate-like portions LI adjacent to each other in the Y direction.

As described above, since the stacked body LMs outside at least the plate-like portion LId in the Y direction is not replaced, the stacked body LMs does not need to be supported by the plurality of pillars PL and PLd. Therefore, the plurality of pillars PL and PLd are not disposed in a region outside the plate-like portion LId in the Y direction, and as a result, it is possible to further reduce the dummy block region BLKd.

According to the semiconductor memory device 1, the pillar PLd disposed in the region between the plate-like portions LId and LI is a dummy pillar. As such, when the pillar PLd in which processing errors and positional deviation are likely to occur is set as a dummy pillar not contributing to the function of the semiconductor memory device 1, it is possible to improve a quality of the semiconductor memory device 1.

### Modification Example

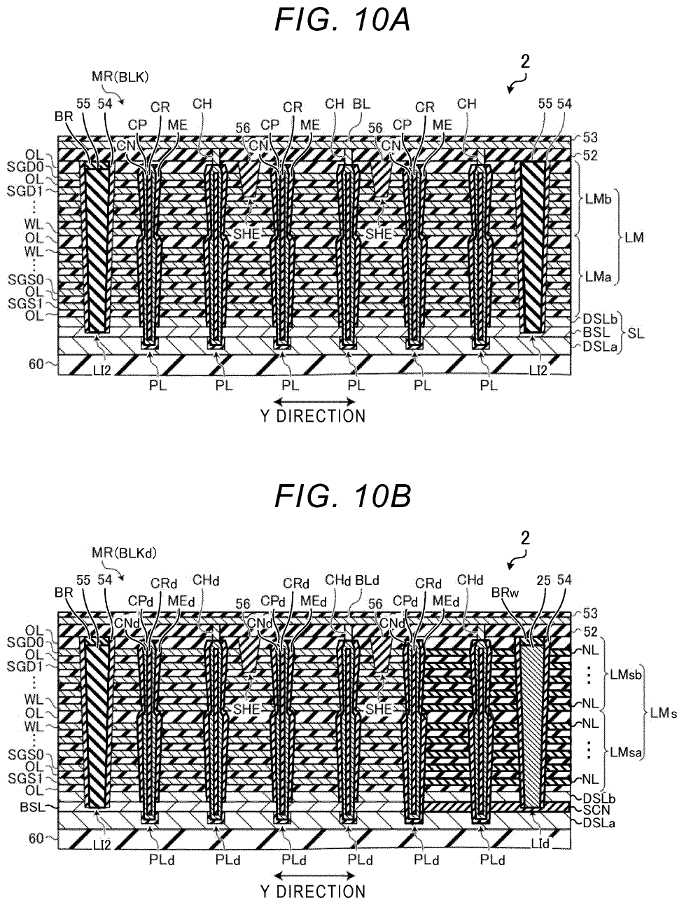

Next, a semiconductor memory device 2 according to a modification example will be described with reference to FIGS. 10A and 10B. The semiconductor memory device 2 of the modification example is different from the semiconductor memory device 1 described above in that a plurality of plate-like portions LI2 do not include the conductive layer 24.

FIGS. 10A and 10B are cross-sectional views showing a structure of the semiconductor memory device 2 according to the modification example.

More specifically, FIG. 10A is a cross-sectional view along the Y direction in the memory region MR of the semiconductor memory device 2 and shows a cross section in the Y direction in the block region BLK. FIG. 10B is a cross-sectional view along the Y direction in the memory region MR of the semiconductor memory device 2 and shows a cross section in the dummy block region BLKd. In FIGS. 10A and 10B, a structure below the insulating layer 60 and a structure above the insulating layer 53 described below are omitted.

In FIGS. 10A and 10B, similar structures to those in the above-described structure are given similar reference signs, and description thereof will not be repeated.

As shown in FIGS. 10A and 10B, the semiconductor memory device 2 includes a plurality of plate-like portions LI2 penetrating the stacked body LM in the stacking direction and extending in the direction along the X direction, instead of the plate-like portions LI of the semiconductor memory device 1 described above.

Each plate-like portion LI2 includes an insulating layer 55 such as a silicon oxide layer instead of the conductive layer 24 provided in the plate-like portion LI described above. That is, the insulating layer 54 is disposed on the side wall of the plate-like portion LI2 facing each other in the Y direction, and the insulating layer 55 is filled inside the insulating layer 54. In an upper end portion of the insulating layer 55, the plurality of bridge portions BR are disposed at predetermined intervals in the X direction.

The plate-like portion LI2 is formed by filling the above-described slits ST with the insulating layer 55 instead of the conductive layer 24 after using the slits ST in replacement of the intermediate source line BSL and the stacked body LM. Since the insulating layers 54 and 55 are formed of the same material such as a silicon oxide layer, a boundary between the insulating layers 54 and 55 may not be distinguished. When the bridge portion BR is a silicon oxide layer or the like, boundaries between the bridge portion BR and the insulating layers 54 and 55 may not be distinguished.

According to the semiconductor memory device 2 of the modification example, the plate-like portion LI2 is filled with the insulating layer 55. Also in such configuration, similar effects to the above-described embodiment are obtained.

The semiconductor memory device 1 or 2 described above includes the stacked body LM and the like, the stacked body LM having a two-tier structure in which the two stacked bodies LMa and LMb are stacked vertically. However, a structure of the stacked body is not limited to the two-tier structure, and may be one-tier structure or a a structure having three or more tiers.

The pillar PL described above is connected to the source line SL on the side surface of the channel layer CN, but the present disclosure is not limited thereto. For example, the memory layer on the bottom surface of the pillar may be removed so that the pillar is connected to the source line in a lower end portion of the channel layer.

The peripheral circuit CBA described above is disposed above the stacked body LM. However, the peripheral circuit may be disposed below the stacked body or may be disposed in the same layer as the stacked body. When the peripheral circuit is disposed below the stacked body, the stacked body can be formed further above the semiconductor substrate on which the peripheral circuit is formed. When the peripheral circuit is disposed in the same layer as the stacked body, the stacked body can be formed at a position different from the peripheral circuit on the semiconductor substrate on which the peripheral circuit is formed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body including a plurality of first layers and a plurality of second layers alternately stacked one by one;
a plurality of slits extending in the stacked body in a stacking direction of the stacked body and in a first direction intersecting the stacking direction, the slits dividing the stacked body in a second direction intersecting the first direction and the stacking direction; and
a plurality of pillars disposed between the plurality of slits and extending in the stacked body in the stacking direction, wherein
an upper end portion of a first slit disposed closest to an end portion of the stacked body in the second direction among the plurality of slits is fully covered with a first strip of first material extending in the first direction and having a width in the second direction that is substantially the same as that of the upper end portion of the first slit, and
an upper end portion of each of a plurality of second slits excluding the first slit among the plurality of slits is partially covered with second strips of the first material, the second strips each having a width in the second direction that is substantially the same as that of the upper end portion of the second slit that the second strips are partially covering.

2. The semiconductor memory device according to claim 1, wherein
the first material is either silicon oxide or polysilicon.

3. The semiconductor memory device according to claim 2, wherein
the first slit is filled with a second material, and
the plurality of second slits is filled with a third material different from the second material.

4. The semiconductor memory device according to claim 3, wherein
the second material is amorphous silicon, and
the third material is a conductive material.

5. The semiconductor memory device according to claim 1, wherein
the stacked body includes:
a first stacked body adjacent to one of the second slits and in which the first layers are conductive layers and the second layers are insulating layers, and
a second stacked body adjacent to the first slit and in which the first layers are insulating layers and the second layers are insulating layers.

6. The semiconductor memory device according to claim 5, wherein
both the first and second stacked bodies are between the first slit and one of the second slits adjacent to the first slit.

7. The semiconductor memory device according to claim 1, wherein
the second strips are arranged in the first direction at predetermined intervals.

8. The semiconductor memory device according to claim 7, wherein
the second strips covering one of the second slits are located along the first direction at the same positions as the second strips covering another of the second slits.

9. The semiconductor memory device according to claim 1, wherein
a side surface of each of the slits is covered by an insulating layer.

10. A semiconductor memory device comprising:
a stacked body including a plurality of conductive first layers and a plurality of second layers alternately stacked one by one;
a plurality of slits extending in the stacked body in a stacking direction of the stacked body and a first direction intersecting the stacking direction, the slits dividing the stacked body in a second direction intersecting the first direction and the stacking direction; and
a plurality of pillars disposed between the plurality of slits and extending in the stacked body in the stacking direction, wherein
a first slit disposed closest to an end portion of the stacked body in the second direction among the plurality of slits and a plurality of second slits excluding the first slit contain different materials and have different layer structures.

11. The semiconductor memory device according to claim 10, wherein
the first slit is filled with a first material containing amorphous silicon, and
each of the second slits is filled with a second material containing silicon oxide.

12. The semiconductor memory device according to claim 11, wherein
the first material further contains silicon oxide.

13. The semiconductor memory device according to claim 10, wherein
the stacked body includes:
a first stacked body adjacent to one of the second slits and in which the first layers are conductive layers and the second layers are insulating layers, and
a second stacked body adjacent to the first slit and in which the first layers are insulating layers and the second layers are insulating layers.

14. The semiconductor memory device according to claim 13, wherein
both the first and second stacked bodies are between the first slit and one of the second slits adjacent to the first slit.

15. The semiconductor memory device according to claim 10, wherein
a side surface of each of the slits is covered by an insulating layer.

16. A method for manufacturing a semiconductor memory device, the method comprising:
forming a stacked body in which a plurality of first insulating layers and a plurality of second insulating layers are alternately stacked one by one;
forming a plurality of pillars extending in the stacked body in a stacking direction of the stacked body;
forming a plurality of slits extending in the stacked body in the stacking direction and in a first direction intersecting the stacking direction such that the stacked body is divided in a second direction intersecting the first direction and the stacking direction;
forming:
a first bridge portion fully covering an upper end portion of a first slit disposed closest to an end portion of the stacked body in the second direction among the plurality of slits, and
second bridge portions each of which covers a part of an upper end portion of each of a plurality of second slits excluding the first slit; and
replacing the plurality of second insulating layers by a plurality of conductive layers via the plurality of second slits.

17. The method according to claim 16, wherein
forming the first and second bridge portions includes:
filling the first slit and the plurality of second slits with a sacrifice layer, and
forming a recess portion for forming the first and second bridge portions in an upper end portion of each of the sacrifice layers.

18. The method according to claim 17, wherein
replacing includes removing the sacrifice layer filled in the second slit from openings between the second bridge portions covering portions of each of the plurality of second slits.

19. The method according to claim 18, wherein
after the plurality of second insulating layers are replaced by the plurality of conductive layers, the plurality of second slits are filled with a material different from the sacrifice layer.
